(19) United States
(12) Patent Application Publication
(10) Pub. No.: US 2007/0064491 A1
(43) Pub. Date: Mar. 22, 2007

(54) Radio resource management

(76) Inventors: Jonathan P. Wallington, Bristol (GB); Davood Molkdar, Chandlers Ford (GB)

Correspondence Address: MOTOROLA, INC., 1303 EAST ALGONQUIN ROAD, IL01/3RD, SCHAUMBURG, IL, 60196, US

(21) Appl. No.: 10/573,005

(22) PCT Filed: Sep. 2, 2004
(86) PCT No.: PCT/EP04/52008

§ 371 Date: Mar. 21, 2006

(30) Foreign Application Priority Data
Nov. 28, 2003 (GB) 0327798.5

(51) Int. Cl. G11C 11/34

(52) U.S. Cl. 365/185.23

(57) ABSTRACT

The present invention relates to radio resource management in a wireless communication system. Specifically, the present invention relates to a method and apparatus for a method of managing downlink radio resources for a multi-sector base transceiver site in which power can be shared between the sectors in which radio resource management decisions are made on the basis of modified reported power measurements.

The present invention relates to radio resource management in a wireless communication system. Specifically, the present invention relates to a method for radio resource management and a corresponding apparatus therefor. The invention is particularly applicable to a multi-sector base transceiver site in which power can be shared between the sectors.

In wireless communication systems, a user device, which is typically mobile, is in wireless communication with a base transceiver station, which generally provides a communication connection to other user devices in wireless communication with the base transceiver station, or with other user devices attached to a communication system to which the base transceiver station belongs, such as a cellular communication system, or with an external network such as the public switched telephone network (PSTN) or the Internet for example. The direction from the user device to the base transceiver station is called uplink and the direction from the base transceiver station to the user device is called downlink.

In general, a base transceiver station has a receive section and a transmit section. The receive section receives uplink radio frequency signals from the user device via an antenna, mixes the received radio frequency signal to obtain a base band signal and demodulates/decodes the resulting base band signal to obtain the received data, for example signaling or message data or user data for onward transmission to a destination, for example to another user device via a cellular communication system to which the base transceiver station belongs.

The transmit section receives data for transmitting to a user device in contact with the base transceiver station, modulates/codes the data to obtain a base band signal for the user, and then mixes the base band signal to receive a radio frequency signal for the user. The radio frequency signal for the base transceiver station, i.e. the cumulative radio frequency signal for all user devices, is then amplified by a power amplifier prior to being transmitted via the base transceiver station antenna.

In order to increase capacity in the communication system, a base transceiver station site may be sub-divided into separate sectors or cells, each of the sectors or cells being provided with a separate power amplifier and antenna. In this situation it may be advantageous to pool the power amplifier resources of the sectors of a multi-sector base transceiver station.

This can be achieved by sharing signals to be amplified for each sector across all of the power amplifiers i.e. N input signals are split and are then recombined into N new signals after amplification by the power amplifiers.

This arrangement enables the required dynamic range of each of the power amplifiers to be reduced, as the signal amplification is shared across a pooled resource of power amplifiers, leading to a reduction in cost of the power amplifiers. This is particularly important in Code Division Multiple Access (CDMA) systems due to the inherently large dynamic range of the resulting aggregate signal, which requires linear amplification. In addition, this arrangement provides automatic power amplifier redundancy, since failure of one of the power amplifiers will not result in a sector losing all power amplification. Finally, this arrangement can enable power sharing between different systems, e.g. AMPS and IS95 systems, where the base transceiver stations are co-located.

In general, the radio resources available to a base site are finite, and are divided by frequency and/or time and/or codes into a number of physical and logical channels, according to the wireless technology employed. A base transceiver station typically supports a number of user devices, and therefore the radio resources i.e. the different channels available to the base station must be allocated to the different user devices. In general, this allocation is handled by a Radio Resource Management function.

In many systems, some Radio Resource Management functions may depend at least partially on the total power available per cell. This is particularly true of Code Division Multiple Access (CDMA) systems, in which downlink Radio Resource Management functions such as admission control and scheduling of users are generally based on the number of code channels available and on the total transmit power available per cell. In most CDMA systems, the number of orthogonal codes available is sufficient and does not generally impose a limitation. Therefore, the system capacity is limited by the maximum transmit power capability of the cell, which in turn is governed by the rated power of the base transceiver station power amplifier.

The Radio Resource Management function generally relies on power measurements from the base transceiver station, in particular the per user code power and the total transmit carrier power to determine how close each individual cell is to the maximum capacity of the cell i.e. the rated power of the amplifier.

The present invention seeks to provide radio resource management for a multi-sector base transceiver station that more effectively utilizes shared power amplifier resources.

According to a first aspect of the present invention, there is provided a method of determining a downlink power allocation as claimed in claim 1.

According to a second aspect of the present invention, there is provided an apparatus for determining a downlink power allocation as claimed in claim 10.

For a better understanding of the present invention, and to show how it may be brought into effect, reference will now be made, by way of example, to the accompanying drawings, in which:

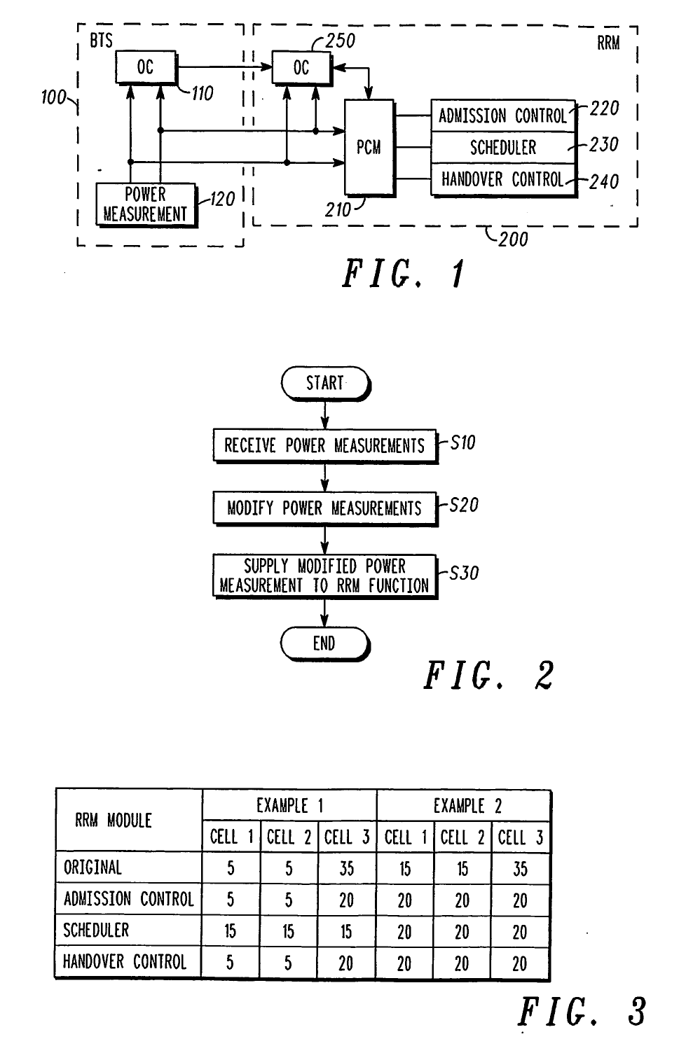

FIG. 1 illustrates the main functional blocks in a base transceiver station, and a radio resource management unit in accordance with an embodiment;

FIG. 2 is a flow chart illustrating the method of operation of the power modifying algorithm shown in FIG. 1; and

FIG. 3 is a table showing exemplary modified power requirement information generated by the power modifying algorithm.

The present invention will be described in the context of a CDMA cellular communication system, as the invention is particularly applicable to such systems in which cell capacity is power or interference limited. However, the invention is not intended to be limited to such systems.

FIG. 1 illustrates the main functional blocks in a base transceiver station (BTS) 100 in accordance with an embodiment, and a radio resource manager (RRM) 200. Only those functions necessary to an understanding of the invention have been shown and will be described. However, a skilled person will appreciate that a practical implementation of the invention would include other functional units, which have been omitted from the present description for clarity.

The radio resource manager (RRM) 200 is typically located in a base station controller (BSC) in a Global System for Mobile Communication (GSM) system or a Radio Network Controller (RNC) in Universal Mobile Telecommunication System (UMTS). However, the RRM 200 may be co-located with the base transceiver station 100 (also called a node B in UMTS terminology) or in any other appropriate network element in a communication system, as will be apparent to a skilled person.

In the described embodiment the BTS 100 is a multi-sector BTS site, having 3 sectors, with pooled power amplifiers. In addition it is assumed that each sector has a maximum power of 20 Watts i.e. each of the power amplifiers is rated at a maximum output power of 20 Watts and thus the total combined transmit power of the multi-sector BTS site is 60 Watts. Clearly, the number of sectors in the multi-sector site and the maximum power described in connection with this embodiment are not essential, and other embodiments may be implemented with differing values.

The BTS 100 is provided with a power measurement function module 110 that generates required power output measurements for each sector, for example a measurement of the total downlink transmission power required for each sector. The power measurement function module 110 is operably coupled to the RRM 200 and passes the power output measurements to the RRM 200. This might be done by way of measurement reports. Such measurement reports may be generated continually, and/or may be generated in response to specific events or triggers.

In addition, the BTS 100 may also be provided with a BTS overload control module 120. If so, the power measurement function module 110 may also be coupled to the BTS overload control module 120, and may also pass the power output measurements to the BTS overload control module 120.

The RRM 200 is operably coupled to the power measurement function module 110 of the BTS 100, as described above, to receive the power output measurements. As indicated above, the RRM 200 is generally located at the BSC, in a GSM system, or in the RNC in a UMTS system, and in this situation the power output measurements are sent across the BTS/BSC interface (Abis interface) or the RNC/NodeB interface (lub interface). Clearly, the exact details of this transfer will be apparent to a skilled person, and so will not be described further.

The RRM 200 in accordance with the illustrated exemplary embodiment comprises a power modifying module 210 together with various different radio resource management function modules. Exemplary illustrated radio resource management modules are: admission control module 220; scheduler 230; and handover control module 240. In addition the RRM 200 also comprises an RRM overload control module 250.

The various RRM modules described and others that will be known to the skilled person but have been omitted for clarity, use transmit power measurements to determine operation of the base station, as will be known by a skilled person. Specifically, the admission control module 220 uses transmit power measurements in determining whether new user devices can be admitted to the cell/sector; scheduler 230 uses transmit power measurements in determining what code and power should be allocated during scheduling of downlink transmissions to a user device; handover control module 240 uses the transmit power measurements in determining whether to handover some user devices to a less heavily loaded cell; and the RRM overload control module 250 uses transmit power measurements to determine overload of each sector.

It is envisaged that the power measurement function module 110, and, if present, the BTS overload control module 120 would generally be implemented as separate software modules within the BTS 100. In addition, it is generally envisaged that the power modifying module 210, admission control module 220, scheduler 230, handover control module 240, and RRM overload control module 250 would generally be implemented as separate software modules within the RRM 200. However, the invention is not intended to be limited to the use of software modules, and the functionality described may be provided by software, hardware, firmware or any combination thereof, as will be apparent to a skilled person.

In one embodiment of the invention the power modifying module 210 is equipped with a multi-bandwidth filter to determine short, medium and long term power requirements of each sector at a base site. The power modifying module 210 may use this information to activate different levels of power borrowing from one sector to another sector. In addition the power modifying module 210 may use this information differently for different RRM functions, as will be explained below.

FIG. 2 is a flow chart illustrating the method of operation of the power modifying module 210 shown in FIG. 1.

Firstly, in step s10, the power modifying module 210 receives the transmit power measurements for each of the sectors from the power measurement module 110, as described above. Then, step s20, the power modifying module 210 adjusts or modifies the power measurements for at least one of the sectors and/or for at least one of the RRM modules. This adjustment or modification may be in accordance with a power scaling algorithm, which will be discussed in further detail below, and/or may be as a result of filtering, as described below. Finally, in step s30, the power modifying module 210 supplies the modified power measurements per sector to RRM functions, in this case the RRM modules 220-240. In addition, it should be noted that the RRM functions, in this case the RRM modules 220-240, may receive differently modified power measurements, as will be explained in more detail below. In addition, the power modifying module 210 may send the modified power requirement measurements per sector to the RRM overload control module 250 (not shown in FIG. 2).

In the most general case, it should be noted that the modifications made to the power measurements received from the BTS 100 may relate to a scaling or adjustment to the reported power in one or more sector. Alternatively or additionally, the modifications made to the power measurements received from the BTS 100 may relate to the application of a short, medium or long term filter to the power measurements, to obtain long term, medium term or short term average values and/or variance information. In some embodiments where both scaling and filtering modifications are applied, the filtering modification is advantageously applied to the scaled values. In other embodiments, it may be advantageous to scale the filtered values. This scaling and filtering may be applied in either order.

It should be noted that it is not necessary that the adjustments or modifications made by the power modifying module 210 in step s20 are identical for all function modules and the RRM overload control module 250. Indeed, in view of the different requirements of the different RRM functions in some embodiments the power modifying module 210 may generate respective modified power measurements for two or more of the RRM function modules 220-240 and the RRM overload control module 250. The principles and examples described below may therefore apply to one or more of individual modifications or adjustments, or to a modification or adjustment to be applied to all RRM modules.

Clearly, a number of different ways of implementing the power modifying module 210 are possible, and the principles on which the power modifying module operates to modify the power measurements may be adapted depending on the desired effect.

The power modifying module 210 may operate to alter one or more of the reported power requirement measurements. The power modifying module 210 generally will make modifications to the relative reported powers to effect an improved allocation of power resources between sectors. Thus for example, a heavily loaded sector may be allocated more power than a single sector rated power, in order to improve the overall site power utilization.

Thus, short to long term filtered values may be considered collectively or independently to determine an optimum level of power to be allocated per cell and/or to provide appropriate time dependent inputs to RRM functions and algorithms, such that RRM algorithms are aware of the SPS capability and allocate resources to use it optimally, eg by allocating more than a single sector rated power to a heavily loaded sector, thus increasing the site capacity. The filtered values are structured such that responses to both long term and short term variations in load are dealt with optimally.

FIG. 3 is a table showing exemplary power scaling information generated by the power modifying module 210 operating in accordance with FIG. 3.

In the first example, the reported power is 5 W-5 W-35 W. In this situation, cells 1 and 2 are lightly loaded and cell 3 is very heavily loaded. However, the total power being used by the 3 cells is only 45 W, which is within the site power capacity of 60 W. If these reported powers were provided directly to the RRM modules 220-240 the overload in cell 3 would result in the RRM modules 220-240 reducing the power requirements of cell 3, for example by reducing the power available to existing users in cell 3, not admitting new users to cell 3 and handing some users to a less heavily loaded cell, for example cell 1 or cell 2, if possible. This leads to an inefficient usage of the available power at the base site.

Instead, in accordance with the exemplary embodiment, the reported powers are modified by the power modifying module 210 prior to being passed to the RRM modules 220-240. Moreover, the reported powers are modified differently for different RRM modules 220-240.

In the exemplary embodiment, the power modifying module 210 modifies the reported powers to 5 W-5 W-20 W prior to passing the power measurements to the admission control module 220. These reported powers will result in the admission control module 220 allowing further users in cells 1 and 2 (as the reported powers are less than the nominal cell power of 20 W), but will not allow any further users into cell 3 (as the reported power is at the maximum nominal cell power of 20 W). Thus the usage of cell 3 may be contained to prevent usage of cell 3 growing in a run away situation, and further use of cells 1 and 2 is still permitted.

In this exemplary embodiment the power modifying module 210 modifies the reported powers to 15 W-15 W-15 W prior to passing the power measurements to the scheduler 230. The scheduler 230 will then allow an extra 5 W (i.e. up to the nominal maximum power of 20 W) to be scheduled for existing users in any cell. This will enable further use of the overloaded cell 3 (which would not have been permitted if the true measurement of 35 W had been received by the scheduler 230) thus allowing the power resources to be used where they are most needed. In addition, the lightly loaded cells 1 and 2 are also allowed to schedule a further 5 W for existing users, thus not unfairly limiting capacity in these cells.

In this exemplary embodiment, the power modifying module 210 modifies the reported powers to 5 W-5 W-20 W prior to passing the power measurements to handover control module 240. The handover control module 240 will thus believe that cell 3 is at the nominal power limit of 20 W. Depending on the algorithm implemented, the handover control module 240 may take no action, but merely monitor the situation further, or alternatively may take steps to handover some users to a neighboring cell. In either case, the number of users that will be handed over from heavily loaded cell 3 to other cells will be significantly less than would have been the case had the true cell 3 power of 35 W been reported. Since the true power of 5 W is reported for cells 1 and 2, which is well within the nominal power limit of 20 W the handover control module will take no action for these cells.

In the second example, the reported power is 15 W-15 W-35 W. In this situation, cells 1 and 2 are reasonably heavily loaded and cell 3 is very heavily loaded. The total power being used by the 3 cells is 65 W, which is slightly greater than the site power capacity of 60 W. If these reported powers were provided directly to the RRM modules 220-240 the overload in cell 3 would result in the RRM modules 220-240 significantly reducing the power requirements of cell 3, for example by reducing the power available to existing users in cell 3, not admitting new users to cell 3 and handing some users to a less heavily loaded cell, for example cell 1 or cell 2, if possible. This leads to an inefficient usage of the available power at the base site.

Instead, in accordance with the exemplary embodiment, the reported powers are modified by the power modifying module 210 prior to being passed to the RRM modules 220-240.

In the exemplary embodiment, the power modifying module 210 modifies the reported powers to 20 W-20 W-20 W prior to passing the power measurements to the admission control module 220. These reported powers will result in the admission control module 220 preventing further users entering any cell (as the reported power for all cells is at the maximum nominal cell power of 20 W). Thus the number of users in the three cells is stabilized.

In this exemplary embodiment the power modifying module 210 modifies the reported powers to 20 W-20 W-20 W prior to passing the power measurements to the scheduler 230. Since the scheduler 230 will believe that all cells are at the maximum nominal cell capacity, the scheduler 230 will not schedule any extra power for existing users in any cell. Again, this will stabilize the power requirements of the cells and prevent further growth in the power requirement.

In this exemplary embodiment, the power modifying module 210 modifies the reported powers to 20 W-20 W-20 W prior to passing the power measurements to handover control module 240. The handover control module 240 will thus believe that all cells are at the nominal power limit of 20 W. Depending on the algorithm implemented, the handover control module 240 may take no action, but merely monitor the situation further, or alternatively may take steps to handover some users to a neighboring cell. In either case, the number of users that will be handed over from heavily loaded cell 3 to other cells will be significantly less than would have been the case had the true cell 3 power of 35 W been reported. The number of users handed over from cells 1 and 2 to another cell (apart from cell 3) will be more than if the true powers of cell 1 and 2, namely 15 W; were reported, leading to a reduction on the total load on the Node B.

Thus as a result of the action of the power modifying module 210 in modifying the reported powers, the radio resource management is improved and optimum use can be made of the base site power resources. If, as in the first example of the exemplary embodiment, the power modifying module 210 makes different modifications depending on the RRM module, the modifications may result in an optimal improved performance of each RRM module, leading to improved overall radio resource management and improved system operation.

In the above exemplary embodiment, the scaled power measurements are passed directly to the respective RRM modules. However, as indicated above, the power values may be applied to a filter and the average of the filter may be passed to the different RRM modules. The power values may be the original measured powers or may be the scaled powers as discussed above. In one embodiment, the power modifying module 210 is supplied with filters that supply averaged values over specific periods of time. In addition, as indicated above, the scaling function described above may be applied to the output of the filter.

Thus for example, the power values for the admission control RRM module 220 may be applied to a filter that supplies a long term average power value. In this context long term may relate to averaging values over a period of the order of minutes or tens of minutes. This enables the admission control module to make decisions based on long term loading of the cells, instead of taking short term fluctuations into account.

In contrast, the scheduler operates on a shorter time frame. Therefore the power values for the scheduler RRM module 230 may be applied to a filter that supplies a short term average power value. In this context short term may relate to averaging values over a period of the order of tens of frames. This enables the scheduler to make decisions based on the short term loading of the cells.

Another example of a Radio Resource Management module that would benefit from operating on filtered or averaged values is a cell breathing module, that operates to alter the pilot transmit power of a cell, hence altering the cell size. Preferably such decisions should be made on power values averaged over a longer time period term, such as over an hour or more.

As mentioned above, the RRM overload control module 250 receives overload alarms from the BTS overload control module 120 and also monitors the overall loading on the BTS site. In addition, the RRM overload module also provides overload information to the power modifying module 210.

The power modifying module 210 monitors the overload information, to determine whether the overload control alarms are site-based or sector based. From this information the power modifying module 210 may alter the nominal power available information for the site or for a sector. So, for example, the power modifying module may systematically allocate more power than the nominal rated power and take account of the reported overload control alarms to determine the optimum power per sector or for the base site. If it is determined that no overload control alarms are generated even when, say, 66 W of power are allocated to the base site, the power modifying module can use this information to modify the total available power to 66 W.

It should be noted that the use of overload control alarms to determine the actual power per sector or per site, as opposed to the nominal rated power, can be effective even in the absence of power sharing in a BTS site. In this situation, the power modifying module 210 will modify the powers reported to the RRM modules 220-240 according to the optimum power for that sector.

Moreover, the power modifying module 210 may become aware of a change in the nominal power available at the base site, for example the failure of one of the power amplifiers. In this situation, the power scaling module will scale the reported measurements to take the total power available into account. The implementation of the invention may result in one or more of the following advantages:
capacity gains may be realized, as more users may be accommodated on more heavily loaded sectors by diverting some unused power from less heavily loaded sectors to the heavily loaded sectors;
more effective management of overload control is possible, leading to an increase in capacity even where the power sharing is not implemented at the base site;
optimization of each radio resource management function is possible since differently modified measured power requirement value may be supplied to different radio resource management functions.

Thus in the described embodiments, an algorithm is introduced at the radio resource manager that modifies the reported power measurements prior to processing by the radio resource manager functions to more efficiently use base site power resources in a multi-sector base site. In addition an overload control function is disclosed that enables power useage to be optimized by enabling the true power capacity of a base site, or of a base site sector, to be determined, irrespective of whether power sharing between sectors is implemented.

Although in the exemplary embodiment shown in FIG. 1 the power modifying module 210 is shown as a separate module from the exemplary RRM modules 220-240, it is not necessary in all embodiments for a separate power modifying module 210 to be provided. Instead the functionality of the power modifying module 210 described above may be implemented as part of each of the RRM modules. In this alternative embodiment, it is envisaged that, in each RRM module, the modification of the power measurement inputs, as described above with reference to FIG. 2, is initially carried out, and the respective RRM module then uses the results thereof in the normal way. Alternatively it would be possible to modify the RRM modules to take the power sharing capability at the base site into account when making radio resource management decisions using the reported power measurements.

1. A method of managing downlink radio resources for the pooling of multiple amplifier resources between sectors of a cell, the method comprising the steps:
receiving downlink power information for each sector of the cell;
filtering the downlink power information to determine different duration power requirements of the sector;
modifying the received downlink power information for each sector of the cell, in response to the different duration power requirements, and such that a more heavily loaded sector will be allocated more power than a less heavily loaded sector; and
making a downlink radio resource management decision on the basis of the different duration power requirements and modified downlink power information such that a more heavily loaded sector will be allocated additional power shared from other sector's amplifiers than would be available from that single sector's amplifier.

2. The method as claimed in claim 1 further comprising the step of determining the available downlink power and using the available downlink power information in the step of determining a downlink power allocation.

3. The method as claimed in claim 2 wherein the available downlink power is determined using information relating to overload control alarms.

4. The method as claimed in claim 2 wherein the determination of a downlink power allocation depends on a comparison of the downlink power information and the available downlink power information.

5. The method as claimed in claim 1 wherein the step of modifying the received downlink power information comprises the step of making a scaling and a filtering modification to the downlink power information resulting in scaled and filtered modified downlink power information; and the step of making a downlink radio resource management decision comprises the step of making a first downlink radio resource management decision on the basis of the scaled modified downlink power information and making a second downlink radio resource management decision on the basis of the filtered modified downlink power information.

6. The method as claimed in claim 1 wherein the modification relates to a scaling and filtering of the downlink power information for at least one cell in a multi-cell base site.

7. The method as claimed in claim 1 wherein the scaling and filtering is carried out differently for different radio resource management decisions.

8. The method as claimed in claim 1 wherein the filtering of the downlink power information includes averaging the power information over different lengths of times.

9. The method as claimed in claim 8 wherein the averaging is performed over different lengths of time for different radio resource management decisions.

10. (canceled)

11. An apparatus for managing downlink radio resources for the pooling of multiple amplifier resources between sectors of a cell, comprising:
means for filtering received downlink power information to determine different duration power requirements of the sector;
means for modifying received downlink power information for each sector of the cell, in response to the different duration power requirements, and such that a more heavily loaded sector will be allocated more power than a less heavily loaded sector; and
means for making a downlink radio resource management decision on the basis of the different duration power requirements and modified downlink power information such that a more heavily loaded sector will be allocated additional power shared from other sector's amplifiers than would be available from that single sector's amplifier.

12. The apparatus as claimed in claim 11 wherein the means for modifying received downlink power information is a power scaling module and a multi-bandwidth filter.

13. The apparatus as claimed in claim 11 wherein the means for making a downlink radio resource management decision on the basis of the modified downlink power information is a radio resource management module.

14. (canceled)
